(19) United States
(12) Patent Application Publication
(10) Pub. No.: US 2026/0170211 A1
(43) Pub. Date: Jun. 18, 2026

(54) MODELING ASYMMETRIC DEGRADATION OF A TRANSISTOR

(71) Applicant: Texas Instruments Incorporated, Dallas, TX (US)

(72) Inventors: Sagnik Dey, Frisco, TX (US); Arif Mohammad Sonnet, Richardson, TX (US); Dhanoop Varghese, Plano, TX (US); Vaibhav Saxena, New Delhi (IN)

(21) Appl. No.: 19/072,639

(22) Filed: Mar. 6, 2025

(30) Foreign Application Priority Data
Dec. 18, 2024 (IN) 202441100234

(51) Int. Cl. G06F 30/3308

(52) U.S. Cl. CPC G06F 30/3308

(57) ABSTRACT

An example apparatus includes: generating a simulation file to simulate a circuit, wherein the circuit includes a transistor including a drain terminal, a source terminal, and a gate terminal, and wherein the simulation file models the transistor with a voltage source coupled to the source terminal; setting a magnitude of the voltage source in the simulation file using an age of the transistor, an estimated voltage at the drain terminal, and an estimated voltage at the gate terminal; and running the simulation file using the magnitude of the voltage source to simulate the circuit.

### CROSS-REFERENCE TO RELATED APPLICATION

This patent application claims the benefit of and priority to Indian Provisional Patent Application No. 202441100234 filed Dec. 18, 2024, which is hereby incorporated herein by reference in its entirety.

### TECHNICAL FIELD

This description relates generally to transistors and, more particularly, to modeling electrical circuits during a design process.

### BACKGROUND

Designers use electronic design tools to design and simulate operation of circuitry before fabrication. Electronic design tools rely upon component models that digitally represent circuit components such as transistors, resistors, capacitors, etc., and those component models are utilized to simulate operations of the circuitry. Some design tools automate the design of manufacturable chips, integrated circuit boards, etc., based on the modeled circuit.

### SUMMARY

For methods and apparatus to model asymmetric degradation of a transistor, an example method includes generating a simulation file to simulate a circuit, where the circuit includes a transistor including a drain terminal, a source terminal, and a gate terminal, and where the simulation file models the transistor with a voltage source coupled to the source terminal. The method includes setting a magnitude of the voltage source in the simulation file using an age of the transistor, an estimated voltage at the drain terminal, and an estimated voltage at the gate terminal. The method includes running the simulation file using the magnitude of the voltage source to simulate the circuit. Other examples are described.

For methods and apparatus to model asymmetric degradation of a transistor, an example at least one non-transitory computer readable storage medium including instructions that, when executed cause programmable circuitry to at least generate a simulation file to simulate a circuit, where the circuit includes a transistor including a drain terminal, a source terminal, and a gate terminal, and where the simulation file models the transistor with a voltage source coupled to the source terminal. The at least one non-transitory computer readable storage medium including instructions that, when executed cause programmable circuitry to at least set a magnitude of the voltage source in the simulation file using an age of the transistor, an estimated voltage at the drain terminal, and an estimated voltage at the gate terminal. at least one non-transitory computer readable storage medium including instructions that, when executed cause programmable circuitry to at least run the simulation file using the magnitude of the voltage source to simulate the circuit. Other examples are described.

For methods and apparatus to model asymmetric degradation of a transistor, an example method includes generating a simulation file to simulate a circuit, where the circuit includes a transistor including a drain terminal and a gate terminal, and where the simulation file models the transistor with a voltage source coupled to the drain terminal. The method includes setting a magnitude of the voltage source in the simulation file using an age of the transistor, an estimated voltage at the drain terminal, and an estimated voltage at the gate terminal. The method includes running the simulation file using the magnitude of the voltage source to simulate the circuit. Other examples are described.

### BRIEF DESCRIPTION OF THE DRAWINGS

FIG. 1 is a schematic diagram of an example aged transistor model including an example transistor and example voltage sources.

FIG. 2 is a block diagram of an example simulation environment for simulating aging of the transistor model of FIG. 1 with an example age degradation module.

FIG. 3 is a block diagram of an example of the age degradation module of FIG. 2.

FIG. 4 is a flowchart representative of example machine-readable instructions or example operations that may be at least one of executed, instantiated, or performed using an example programmable circuitry implementation of the simulation environment of FIG. 2 to simulate aging of the transistor of FIG. 1.

FIG. 5 is a flowchart representative of example machine-readable instructions or example operations that may be at least one of executed, instantiated, or performed using an example programmable circuitry implementation of the age degradation module of FIGS. 2 and 3 or more generally the aging model of FIG. 2.

FIGS. 6A and 6B are plots of example operations of the transistor of FIGS. 1 and 2 and the age determination circuitry of FIGS. 2 and 3.

FIG. 7 is a block diagram of an example processing platform including programmable circuitry structured to execute, instantiate, or perform the example machine-readable instructions or perform the example operations of FIGS. 4 and 5 to implement the age degradation module of FIG. 3.

FIG. 8 is a block diagram of an example implementation of the programmable circuitry of FIG. 7.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

Designers use electronic design tools to design and simulate operation of circuitry before fabrication. Electronic design tools rely upon component models that digitally represent circuit components such as transistors, resistors, capacitors, etc., and those component models are utilized to simulate operations of the circuitry. A designer can construct a model of an electrical circuit and simulate the operation of circuit using the model. The designer can create the circuit model by assembling models of the components in the circuit. Some design tools automate the design of manufacturable chips, integrated circuit boards, etc., based on the modeled circuit.

Electronic design automation (EDA) tools allow designers to design semiconductor devices using a register-transfer level (RTL) design and intellectual property (IP) blocks (also referred to as hard IP blocks). An EDA tool automates the process of selecting, placing, and routing circuitry to produce a fabrication ready semiconductor device. Designing semiconductor devices with an EDA tool begins with developing or selecting any hard IP blocks to perform functions of the semiconductor package. For example, a designer may add a hard IP block that operates as a level 2 (L2) cache of programmable circuitry, such as a central processing unit (CPU).

Designers create RTL designs to perform operations between hard IP blocks or additional operations of the semiconductor device. An RTL design defines target behavior of circuitry of the semiconductor device. Some RTL designs are created using a hardware description language (HDL), such as Verilog, system Verilog, very high-speed integrated circuitry hardware description language (VHSIC or VHDL), etc. Alternatively, designers may create a relatively higher-level abstraction of an RTL design using a programming language, such as C, C++, C-sharp, etc. In such examples, designers use a converter, a compiler, or a synthesis tool to produce the RTL design from the relatively higher-level abstraction.

EDA tools synthesize circuitry to perform the operations of the RTL designs. In some examples, EDA tools determine a net list of circuit components (e.g., a transistor, an amplifier, a resistor, a voltage source, etc.) that when integrated, operate as specified by the RTL design. The EDA implements the circuitry components by selecting cells from a cell library. The cell library is a listing of cells that characterize components both physically (e.g., size, silicon design, etc.) and electrically (e.g., input requirements, output requirements, signal to noise ratio (SNR) specification, etc.). The EDA tool uses one or more cells to form circuitry that performs operations of the RTL design. The EDA tool places and routes cell circuitry of selected cells into a die of the semiconductor device to implement the RTL design.

In operation, an EDA tool may be unable to place and route the cells needed to implement the RTL design in a single pass. For example, the EDA tool may be unsuccessful in placing and routing all components of a design within the boundary of an IC during a first attempt. In such examples, the EDA tool performs multiple attempts to place and route all components of the design within the boundary of the IC. In such operations, the EDA tool will continue to attempt to successfully implement the RTL design by modifying positioning, components, constraints, etc., of the selected cells.

In some examples, a first entity designs the RTL design and runs the EDA tool and a second entity fabricates the semiconductor device. Alternatively, a single entity may design or run an EDA tool to produce a fabrication ready device. In both examples, the fabricating entity is referred to as a semiconductor foundry. Semiconductor foundries develop process design kits (PDKs) to assist electronic design tools, such as EDA tools, in successfully implementing electronic designs for a specific fabrication process. A PDK is a collection of files for modeling fabrication processes. Some PDKs may provide a cell library, verification operations, simulation models, design manuals, optional design considerations, etc. Designers can use PDKs to design, verify, and simulate an electronic design before fabrication. As electronic systems continue to advance, PDKs have begun to support additional modeling, simulation, and verification operations, which allow EDA tools to implement increasingly complex simulations in implementing designs.

Some PDKs allow design tools to verify semiconductor designs across a product lifetime by modeling component aging. For example, during transistor switching, lateral electrical fields can excessively energize charge carriers, which are referred to as hot charge carriers. After traversing a channel of the transistor, the hot charge carriers impact the oxide interface of a transistor close to the drain (drain oxide). The hot charge carrier impacts can result in ionization of charges in the drain oxide. Also, impact ionization can inject hot charge carriers into the gate-oxide through the drain oxide. The injected charge carriers break down the silicon oxide bonds of the drain and gate oxides. Accordingly, as a transistor ages, the resistance at the drain terminal of the transistor increases as hot charge carriers break down more silicon oxide bonds. Such degradation of the transistor is referred to as channel hot carrier (CHC) degradation. As a transistor ages, CHC degradation produces an asymmetry by adversely affecting the terminal with the higher electric field applied where impact ionization occurs.

Some simulation tools model CHC degradation by adding a first resistor to a drain of the transistor and a second resistor to a source of the transistor in the model. At an initial time, such as a time immediately following fabrication, the simulation tool sets the first and second resistors equal to model the initial symmetry between the source and drain terminals of the transistor. After the initial time, the simulation tool models CHC degradation by increasing the resistance of the first resistor to produce an asymmetry between source and drain terminals. The change in the resistance of the first resistor over time represents the change in resistance resulting from the breakdown of silicon oxide bonds. Such a change in resistance is referred to as a damage resistance (R_{damage}). In some examples, the damage resistance is modelled as an additional resistor.

The simulation tool models CHC degradation as the transistor ages by continuing to increase the damage resistance to represent the passage of time. During such modeling, the drain voltage of the transistor decreases responsive to the damage resistance increasing. The transistor current (I_{d}) changes responsive to the change in the drain voltage. The change in transistor current (I_{d}) depends on the damage resistance (R_{damage}) and the output conductance of the transistor (g_{D}). Some simulation tools model the degradation of the transistor current using Equation (1).

$$\frac{Δ {I}_{d}}{{I}_{d}} = \frac{{ℊ}_{D} {R}_{damage}}{( 1 + {ℊ}_{D} {R}_{damage} )} \qquad Equation ( 1 )$$

In operation, the output conductance of the transistor (g_{D}) changes depending on the operating region of the transistor. For example, the output conductance of the transistor (g_{D}) increases as the device transitions from saturation to linear regions. In such examples, as illustrated by Equation (1), the change in current of the transistor responsive to CHC degradation is significantly lower in saturation region. PDKs implement CMOS transistor devices as symmetric elements having interchangeable drain and source terminals. For example, a PDK structures a transistor to have the same resistance at both the drain and source terminals.

As described above, the identical resistances on both the source and drain terminals are sufficient for modeling the transistors performance at an initial time, such as a time without aging. Unfortunately, the source and drain symmetry limits aging models to symmetric degradation, such as both the source and drain resistance increasing with time. By symmetrically degrading both source and drain resistances of the transistor, the aging model over predicts degradation of the transistor current in saturation region and does not account for the CHC degradation, which is asymmetric. An over prediction of degradation may result in an EDA tool determining that a semiconductor device layout does not meet product lifetime requirements. Such a determination may result in the EDA tool having to redesign the semiconductor device. In relatively complex semiconductor designs, redesigning the semiconductor device may take an extensive amount of time and compute resources.

Examples described herein include methods, systems, and apparatus to model asymmetric degradation of a transistor. In some described examples, a transistor aging model includes a transistor, a first voltage source, a second voltage source, and an age degradation module. The transistor aging model represents an aging simulation of the transistor by a design tool for CHC degradation. In the described examples, the modelled transistor has a drain terminal, a source terminal, and a control terminal. In the model, the first voltage source is coupled to the drain terminal of the transistor. The second voltage source is coupled to the source terminal of the transistor. In some examples, the first and second voltage sources are implemented using an HDL, such as Verilog, VHDL, etc. In such examples, the first and second voltage sources may be referred to as Verilog voltage sources. The age degradation module controls the first and second voltage sources to model asymmetric aging of the transistor.

In example operations, the age degradation module sets the first and second voltage sources to zero volts at an initial time, which replicates an initial performance of the transistor. In such example operations, the age degradation module determines voltages of the transistor, such as a drain voltage (V_{D}) and a gate voltage (V_{G}). After the initial time, the age degradation module determines a damage resistance for a given time as a function of the drain voltage, the gate voltage, and the age of the transistor. The age degradation module determines a total damage resistance of the transistor by accumulating the determined damage over time. The age degradation module determines a change in voltage at least one of the drain or source terminals of the transistor by multiplying the accumulated damage resistance by the transistor current. The age degradation module models the asymmetric CHC degradation of by setting one of the first or second voltage sources to the determined voltage.

Advantageously, the age degradation module may accurately simulate or model the asymmetric CHC degradation on either side of the transistor by changing the first or second voltage source. Advantageously, the age degradation module can track CHC degradation across a range of voltages of the transistor. Advantageously, the system model accurately models CHC degradation in both linear and saturation regions. Advantageously, the system model reduces over-prediction of the ionization of carrier charges at a terminal of a transistor model.

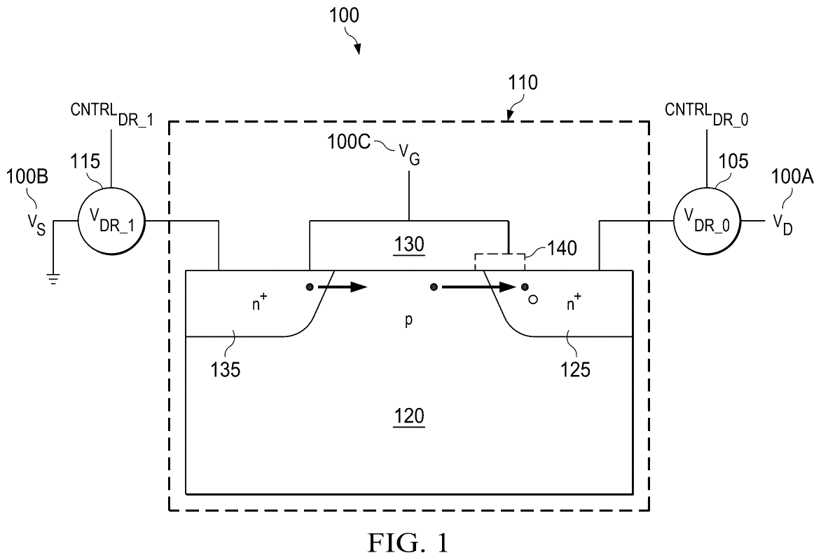

FIG. 1 is a schematic diagram of an example transistor model 100. In the example of FIG. 1, the transistor model 100 includes first voltage source 105, a transistor 110, and second voltage source 115. The example transistor 110 of FIG. 1 includes an example substrate 120, a drain region 125, a gate region 130, a source region 135, and an example ionization region 140. In the example of FIG. 1, the transistor 110 illustratively represents a fabricated transistor package.

The features of transistor 110 shown in FIG. 1 (e.g., the substrate 120, the drain region 125, the gate region 130, and the source region 135) will exist in the transistor that is eventually fabricated. However, the voltage sources 105 and 115 will not be present in the transistor that is eventually fabricated. The voltage sources 105 and 115 are part of the transistor model 100 that is used to simulate the circuit behavior during the design and/or verification processes.

The example transistor model 100 of FIG. 1 illustrates an example simulation of the transistor 110 by an EDA tool across time. The transistor model 100 has a drain terminal 100A, a source terminal 100B, and a gate terminal 100C. The drain terminal 100A of the transistor model 100 is structured to be coupled to a simulation of another component of a semiconductor device. For example, the drain terminal of the transistor model 100 may be coupled to an IP block or components implementing an RTL design. The source terminal 100B of the transistor model 100 is coupled to a simulation of a common terminal, which provides a common potential (e.g., ground, AVSS, etc.). Alternatively, similar to the drain terminal of the transistor model 100, the source terminal of the transistor model 100 may be coupled to an IP block or another component of a semiconductor device. The gate terminal 100C of the transistor model 100 is structured to be coupled to an IP block or another component of the semiconductor device. In some examples, the gate terminal of the transistor model 100 is referred to as a control terminal.

The voltage source 105 is part of the transistor model 100 and has a first terminal, a second terminal, and a control input. The first terminal of the voltage source 105 is coupled to the drain terminal of the transistor model 100 (V_{D}). The second terminal of the voltage source 105 is coupled to the drain region 125 of the transistor 110. The voltage magnitude (V_{DR_0}) across the voltage source 105 can be controlled by simulation software, which is represented in FIG. 1 by a first voltage control (CNRTL_{DR_0}). During a circuit simulation, the voltage source 105 produces a first damage resistance control voltage (V_{DR_0}) responsive to the first voltage control. In example operations, the voltage source 105 is a simulation of a voltage source, which may be referred to as a Verilog voltage source.

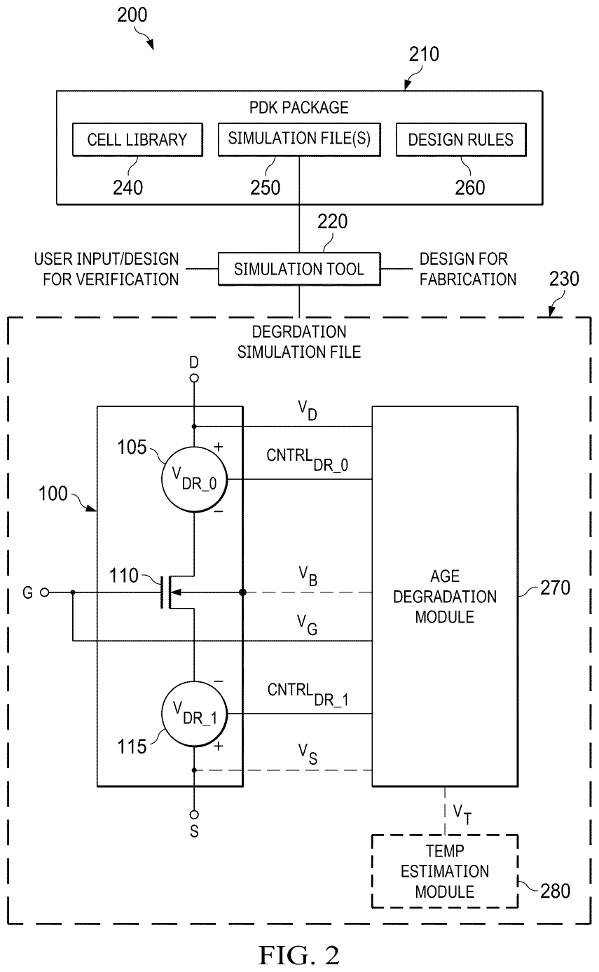

The transistor 110 has a first terminal, a second terminal, and a third terminal. The first terminal of the transistor 110 is coupled to the voltage source 105. The second terminal of the transistor 110 is coupled to the voltage source 115. The third terminal of the transistor 110 is coupled to the gate terminal of the transistor model 100 (V_{G}). In some examples, the transistor 110 is illustrated or described in connection with physical or electrical characteristics. For example, the transistor 110 may be illustrated by a physical implementation provided by a corresponding cell. In another example, such as in FIG. 2, the transistor 110 is illustrated by a schematic symbol. In all examples, the transistor 110 may be implemented in a semiconductor package using the regions illustrated in FIG. 1.

The voltage source 115 is part of the transistor model 100 and has a first terminal, a second terminal, and a control input. The first terminal of the voltage source 115 is coupled to the source region 135 of the transistor 110. The second terminal of the voltage source 115 is coupled to the common terminal, which provides the common potential. The voltage magnitude (V_{DR_0}) across the voltage source 115 can be controlled by simulation software, which is represented in FIG. 1 by a second voltage control (CNTRL_{DR_1}). During a circuit simulation, the voltage source 115 produces a first damage resistance control voltage (V_{DR_1}) responsive to the second voltage control. In example operations, the voltage source 115 is a simulation of a voltage source, which may be referred to as a Verilog voltage source.

The substrate 120 is coupled to the drain region 125, the gate region 130, and the source region 135. The example substrate 120 of FIG. 1 is a p-doped semiconductor material. The substrate 120 separates the drain region 125 and the source region 135.

The drain region 125 is coupled to the voltage source 105, the substrate 120, and the gate region 130. In some examples, the drain region 125 is coupled to the gate region 130 by the ionization region 140. The example drain region 125 of FIG. 1 is a n-doped semiconductor material.

The gate region 130 is coupled to the gate terminal of the transistor model 100 (V_{G}), the substrate 120, the drain region 125, and the source region 135. The gate region 130 can be separated from the channel in the substrate 120 by an insulating material, such as an oxide, to impede the flow of electricity between the gate region 130 on the one hand and the channel, the drain region 125, and the source region 135 on the other hand. In some examples, the gate region 130 is coupled to the ionization region 140. Also, in some examples, the gate region 130 is coupled to the substrate 120, the drain region 125, and the source region 135 by an insulating layer or adhesive layer.

The source region 135 is coupled to the voltage source 115, the substrate 120, and the gate region 130. The example source region 135 of FIG. 1 is an n-doped semiconductor material.

The ionization region 140 is coupled to the drain region 125 and the gate region 130. The ionization region 140 is an illustrative representation of a location of impact ionization of hot charge carriers in the transistor 110. However, unlike fabricated transistors, the transistor model 100 does not form the ionization region 140 as a simulation runs. To account for this difference, during the simulation operations described herein, the voltage sources 105, 115 are structured to simulate the formation of the ionization region 140 in the transistor 110. Advantageously, the voltage source 105 replicates the change in performance of the transistor 110 resulting from the ionization region 140 forming. Alternatively, the voltage source 105 can replicate the change in performance of the transistor 110 resulting from an ionization region forming between the gate region 130 and the source region 135.

In the example of FIG. 1, the transistor 110 is an n-channel metal-oxide semiconductor field-effect transistor (MOSFET). Alternatively, the transistor 110 may be an n-channel field-effect transistor (FET), an n-channel insulated-gate bipolar transistor (IGBT), an n-channel junction field effect transistor (JFET), an NPN bipolar junction transistor (BJT) or, with slight modifications, a p-type equivalent device. In some examples, the transistor 110 may be a depletion mode device a drain-extended device, an enhancement mode device, a natural transistor or other type of device structure transistor. Furthermore, the transistor 110 may be implemented in/over a silicon substrate (Si), a silicon carbide substrate (SiC), a gallium nitride substrate (GaN) or a gallium arsenide substrate (GaAs).

FIG. 2 is a block diagram of an example simulation environment 200 including an example PDK package 210, an example simulation tool 220, and an example degradation simulation file 230. The example PDK package 210 of FIG. 2 includes an example cell library 240, example simulation file(s) 250, and example design rules 260. Alternatively, the PDK package 210 of FIG. 2 may include any number or combination of components. The example degradation simulation file 230 of FIG. 2 includes the transistor model 100 of FIG. 1, an example age degradation module 270, and an example temperature estimation module 280. The example transistor model 100 of FIG. 2 includes the voltage sources 105, 115 of FIG. 1 and the transistor 110 of FIG. 1.

The simulation environment 200 is an illustrative representation of an electronic design tool, such as an EDA tool, during a design verification process. In some examples, the electronic design tool forms the degradation simulation file 230 using data of the PDK package 210 and an electronic design. In the example of FIG. 2, the simulation environment 200 simulates CHC degradation of the transistor 110 to verify an electronic design meets product lifetime specifications.

The PDK package 210 is a collection of resources that, when implemented, allow designers to run simulations for design verification. In some examples, a semiconductor foundry develops and provides the PDK package 210 to verify designs before fabrication. For example, the PDK package 210 includes design rules that constrain placement, layer design, etc., based on a fabrication process. The PDK package 210 allows designers to replicate a post fabrication semiconductor device using virtual models of different components. This replication can allow the designer to catch and correct any issues in the circuit model investing the time and expense in fabricating the physical circuit.

The simulation tool 220 provides an interface for creation and simulation of electrical designs using components of the PDK package 210. In some examples, the simulation tool 220 allows users to select, place, and route different electrical components to implement an electrical design. In other examples, the simulation tool 220 is a part of an EDA tool, which automates selecting, placing, and routing electrical components to implement an RTL design. In both examples, the simulation tool 220 creates and populates the degradation simulation file 230 using the PDK package 210. The simulation tool 220 runs the degradation simulation file 230 to determine if the electrical design meets specifications.

The degradation simulation file 230 of FIG. 2 illustratively represents a combination of components to simulate CHC degradation of the transistor 110. In some examples, the simulation tool 220 produces the degradation simulation file 230 using components from the PDK package 210. In other examples, the degradation simulation file 230 is a part of the simulation files 250, such as a template simulation file. In such examples, the simulation tool 220 may modify properties of the template simulation file to produce the degradation simulation file 230, which is design specific.

The cell library 240 is a plurality of component cells that a semiconductor foundry can produce. Each component cell of the cell library 240 represents an electrical component, such as a transistor, resistor, capacitor, etc., using electrical and physical characteristics. In some examples, the simulation tool 220 forms the degradation simulation file 230 as a combination of one or more cells of the cell library 240. Also, the cell library 240 may include hard IP blocks that implement intellectual property of another entity.

The simulation files 250 represent operations of different processes or components in a circuit. For example, the simulation files 250 include instructions that define operations of the voltage source 105, the transistor 110, or the age degradation module 270. In some examples, the simulation tool 220 simulates the operations of components of the degradation simulation file 230 by combining operations of one or more of the simulation files 250. The simulation file 250 can include a data representing a schematic or model of a circuit, such as a netlist, a SPICE file, a Verilog file, a VHDL file, or the like.

The design rules 260 represent design constraints or limitations of different operations. For example, a semiconductor foundry adds design rules 260 to reflect fabrication limitations for different manufacturing processes. In other examples, the design rules 260 constrain selection, placement, or routing of different components in the degradation simulation file 230. In such examples, the design rules 260 prevent designs from including designs that cannot be fabricated or simulated.

The age degradation module 270 can be used to control the voltage across voltage sources 105 and/or 115 in a circuit simulation. The age degradation module 270 can use one or more of the following values as inputs: drain voltage, base voltage, gate voltage, source voltage, and the temperature. As shown in FIG. 2, the age degradation module 270 has a first input, a second input, a third input, a fourth input, a fifth input, a first output and a second output. The first input of the age degradation module 270 is coupled to the drain terminal of the transistor model 100 (D). The second input of the age degradation module 270 is coupled to the gate terminal of the transistor model 100 (G). The third input of the age degradation module 270 is coupled to the source terminal of the transistor model 100 (S). The fourth input of the age degradation module 270 is coupled to a bulk terminal (also referred to as a body terminal) of the transistor model 100 (B). The fifth input of the age degradation module 270 is coupled to the temperature estimation module 280. The first output of the age degradation module 270 (V_{DR_0}) is coupled to the voltage source 105 of the transistor model 100. The second output of the age degradation module 270 (V_{DR_1}) is coupled to the voltage source 113 of the transistor model 100.

The temperature estimation module 280 is coupled to the age degradation module 270. In some examples, the temperature estimation module 280 is positioned in proximity to the transistor 110 of the transistor model 100. In some examples, the temperature estimation module 280 is an empirical formula representing a range of temperature conditions or expected temperature conditions.

In the example of FIG. 2, the transistor 110 is an n-channel MOSFET. Alternatively, the transistor 110 may be an n-channel FET, an n-channel IGBT, an n-channel JFET, an NPN BJT or, with slight modifications, a p-type equivalent device. In some examples, the transistor 110 may be a depletion mode device a drain-extended device, an enhancement mode device, a natural transistor or other type of device structure transistor. Furthermore, the transistor 110 may be implemented in/over a silicon substrate (Si), a silicon carbide substrate (SiC), a gallium nitride substrate (GaN) or a gallium arsenide substrate (GaAs).

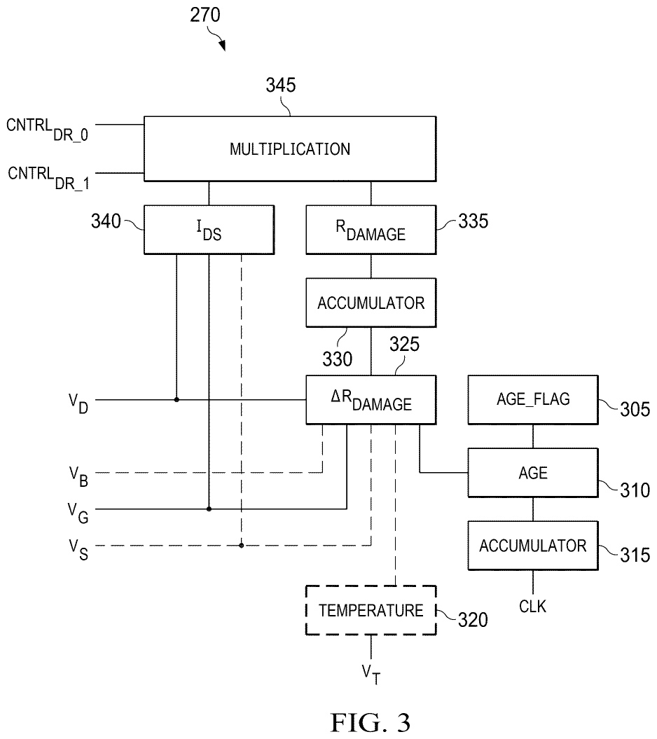

FIG. 3 is a block diagram of an example implementation of the age degradation module 270 of FIG. 2. The age degradation module 270 of FIG. 3 may be instantiated (e.g., creating an instance of, bring into being for any length of time, materialize, implement, etc.) by programmable circuitry such as a Central Processor Unit (CPU) executing first instructions, a field programmable gate array, a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc. Also or alternatively, the age degradation module 270 of FIG. 3 may be instantiated (e.g., creating an instance of, bring into being for any length of time, materialize, implement, etc.) by (i) an Application Specific Integrated Circuit (ASIC) or (ii) a Field Programmable Gate Array (FPGA) structured or configured in response to execution of second instructions to perform operations corresponding to the first instructions. Some or all of the circuitry of FIG. 3 may, thus, be instantiated at the same or different times. Some or all of the circuitry of FIG. 3 may be instantiated, for example, in one or more threads executing concurrently on hardware or in series on hardware. Moreover, in some examples, some or all of the circuitry of FIG. 3 may be implemented by microprocessor circuitry executing instructions or FPGA circuitry performing operations to implement one or more virtual machines or containers. In the example of FIG. 3, the age degradation module 270 includes age flag circuitry 305, age tracking circuitry 310, first accumulator circuitry 315, temperature circuitry 320, channel damage circuitry 325, second accumulator circuitry 330, channel damage tracking circuitry 335, transistor current circuitry 340, and multiplication circuitry 345.

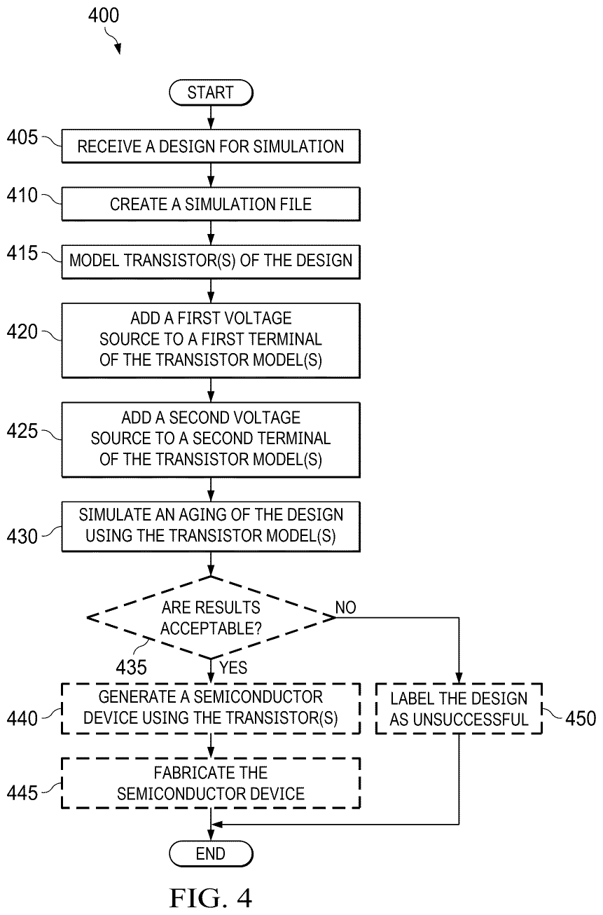

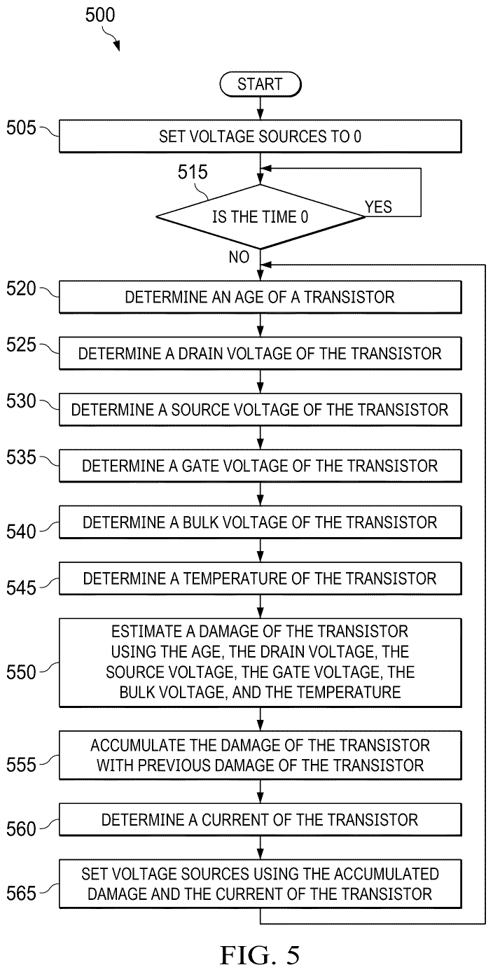

The age degradation module 270 has a first input, a second input, a third input, a fourth input, a fifth input, a first output and a second output. The first input of the age degradation module 270 is coupled to the drain terminal of the transistor model 100 (D). The second input of the age degradation module 270 is coupled to the gate terminal of the transistor model 100 (G). The third input of the age degradation module 270 is coupled to the source terminal of the transistor model 100 (S). The fourth input of the age degradation module 270 is coupled to a bulk terminal (also referred to as a body terminal) of the transistor model 100 (B). The fifth input of the age degradation module 270 is coupled to the temperature estimation module 280. The first output of the age degradation module 270 (CNTRL_{DR_0}) is coupled to the voltage source 105 of the transistor model 100. The second output of the age degradation module 270 (CNTRL_{DR_1}) is coupled to the voltage source 113 of the transistor model 100. In some examples, the age degradation module 270 is instantiated by programmable circuitry executing age determination instructions to perform operations such as those represented by the flowchart(s) of FIGS. 4 and 5.

The age flag circuitry 305 has an output coupled to the age tracking circuitry 310. In some examples, the age flag circuitry 305 is a portion of memory, such as a register or memory location, which specifies whether or not to simulate CHC degradation using the age degradation module 270 and enable bypass simulation of degradation to reduce simulation time during initial time-zero or fresh transistor design phase. In some examples, the age flag circuitry 305 is instantiated by programmable circuitry executing age flag instructions to perform operations such as those represented by the flowchart(s) of FIGS. 4 and 5.

The age tracking circuitry 310 has a first input, a second input, and an output. The first input of the age tracking circuitry 310 is coupled to the age flag circuitry 305. The second input of the age tracking circuitry 310 is coupled to the accumulator circuitry 315. The output of the age tracking circuitry 310 is coupled to the channel damage circuitry 325. In some examples, the age tracking circuitry 310 is instantiated by programmable circuitry executing age tracking instructions to perform operations such as those represented by the flowchart(s) of FIGS. 4 and 5.

The accumulator circuitry 315 has an input and an output. The input of the accumulator circuitry 315 is structured to be coupled to clock circuitry, which provides a clock signal (CLK). The output of the accumulator circuitry 315 is coupled to the age tracking circuitry 310. In some examples, the accumulator circuitry 315 is instantiated by programmable circuitry executing accumulator instructions to perform operations such as those represented by the flowchart(s) of FIGS. 4 and 5.

The temperature circuitry 320 has an input and an output. The input of the temperature circuitry 320 is structured to be coupled to the temperature estimation module 280 of FIG. 2, which provides a temperature voltage (VT). The output of the temperature circuitry 320 is coupled to the channel damage circuitry 325. In some examples, the temperature circuitry 320 is instantiated by programmable circuitry executing temperature instructions to perform operations such as those represented by the flowchart(s) of FIGS. 4 and 5.

The channel damage circuitry 325 has a first input, a second input, a third input, a fourth input, a fifth input, a sixth input, and an output. The first, second, third, and fourth inputs of the channel damage circuitry 325 are respectively coupled to the drain, gate, source, and bulk terminals of the transistor model 100. Th fifth input of the channel damage circuitry 325 is coupled to the age tracking circuitry 310. The sixth input of the channel damage circuitry 325 is coupled to the temperature circuitry 320. The output of the channel damage circuitry 325 is coupled to the accumulator circuitry 330. In some examples, the channel damage circuitry 325 is instantiated by programmable circuitry executing channel damage instructions to perform operations such as those represented by the flowchart(s) of FIGS. 4 and 5.

The accumulator circuitry 330 has an input and an output. The input of the accumulator circuitry 330 is coupled to the channel damage circuitry 325. The output of the accumulator circuitry 330 is coupled to the channel damage tracking circuitry 335. In some examples, the accumulator circuitry 330 is instantiated by programmable circuitry executing accumulator instructions to perform operations such as those represented by the flowchart(s) of FIGS. 4 and 5.

The channel damage tracking circuitry 335 has an input and an output. The input of the channel damage tracking circuitry 335 is coupled to the accumulator circuitry 330. The output of the channel damage tracking circuitry 335 is coupled to the multiplication circuitry 345. In some examples, the channel damage tracking circuitry 335 is instantiated by programmable circuitry executing channel damage tracking instructions to perform operations such as those represented by the flowchart(s) of FIGS. 4 and 5.

The transistor current circuitry 340 has a first input, a second input, a third input, and an output. The first, second, and third inputs of the transistor current circuitry 340 are respectively coupled to the drain, gate, and source terminals of the transistor model 100. The output of the transistor current circuitry 340 is coupled to the multiplication circuitry 345. In some examples, the transistor current circuitry 340 is instantiated by programmable circuitry executing transistor current instructions to perform operations such as those represented by the flowchart(s) of FIGS. 4 and 5.

The multiplication circuitry 345 has a first input, a second input, a first output, and a second output. The first input of the multiplication circuitry 345 is coupled to the channel damage tracking circuitry 335. The second input of the multiplication circuitry 345 is coupled to the transistor current circuitry 340. The first output of the multiplication circuitry 345 is structured to be coupled to the voltage source 105. The second output of the multiplication circuitry 345 is structured to be coupled to the voltage source 115. In some examples, the multiplication circuitry 345 is instantiated by programmable circuitry executing multiplication instructions to perform operations such as those represented by the flowchart(s) of FIGS. 4 and 5.

FIG. 4 is a flowchart representative of example machine-readable instructions or example operations 400 that may be at least one of executed, instantiated, or performed using an example programmable circuitry implementation of the simulation environment 200 of FIG. 2 to simulate aging of the transistor 110 of FIGS. 1 and 2. The example operations 400 begin at Block 405 at which the simulation tool 220 of FIG. 2 receives a design for simulation. In some examples, users interface with the simulation tool 220 to select, place, and route components to form an electrical design for simulation. In other examples, an EDA tool selects, places, and routes components to implement an RTL design. In such examples, the simulation tool 220 is a part of the EDA tool or interfaces with the EDA tool.

The simulation tool 220 creates a simulation file. (Block 410). In example operations, the simulation tool 220 creates a simulation file to simulate a received electrical design. For example, the simulation tool 220 creates the degradation simulation file 230 of FIG. 2. Also, the simulation tool 220 may create one or more additional files to simulate additional operations, such as the operations of components coupled to terminals of the transistor model 100.

The degradation simulation file 230 models transistor(s) of the design. (Block 415). In some examples, the cell library 240 of FIG. 2 includes component cells that characterize electrical components. In such examples, the simulation files 250 of FIG. 2 include operations to model operation of components of the cell library 240. In example operations, the degradation simulation file 230 models the transistor 110 responsive to the simulation tool 220 selecting a cell of the cell library 240. In such example operations, the degradation simulation file 230 also includes the data of the simulation files 250 that corresponds to the operations of the transistor 110.

The PDK package 210 adds a first voltage source to a first terminal of the transistor model(s). (Block 420). The PDK package 210 adds a second voltage source to a second terminal of the transistor model(s). (Block 425). In example operations, the PDK package 210 includes a series of design rules for simulating CHC degradation of the transistor 110. In such example operations, the PDK package 210 adds the voltage source 105, 115 to the degradation simulation file 230 to form the transistor model 100.

The simulation tool 220 simulates aging of the design using the transistor model(s). (Block 430). In example operations, the simulation tool 220 executes machine-readable instructions to digitally simulate operations of the electronic design, specifically, the degradation simulation file 230. In some examples, the simulation tool 220 simultaneously runs a plurality simulation files to simulate operations of an electrical design including a plurality of components. In such examples, the simulation tool 220 simulates operations of a semiconductor device to verify a plurality of design specifications. In such example operations, the simulation tool 220 executes machine-readable instructions to instantiate the age degradation module 270. Such example operations of the age degradation module 270, or more generally the simulation of the degradation simulation file 230 are further illustrated and described in connection with FIG. 5.

In some examples, as illustrated by the dashed lines, the simulation tool 220 determines if results of running the simulation file are acceptable. (Block 435). In example operations, the simulation tool 220 receives design specifications for the electrical design. During the simulation of the transistor model 100, the simulation tool 220 compares a performance of the simulation to the design specifications. For example, the simulation tool 220 determines that the electronic design does not meet a product lifetime specification if the transistor 110 no longer conducts current after four simulated years and the product lifetime specification is five years.

If the simulation tool 220 determines that the results of running the simulation file are acceptable (e.g., Block 435 returns a result of YES), an EDA tool generates a design using the simulation file. (Block 440). In example operation, the EDA tool selects, places, and routes components of the electronic design, including the transistor 110, responsive to a successful simulation. In such examples, the design of the EDA tool is considered to be ready for fabrication.

A semiconductor foundry corresponding to the PDK package 210 fabricates a semiconductor device using the design. (Block 445). In example operations, the PDK package 210 provides the EDA tool access to fabrication information of a semiconductor foundry. In such examples, the semiconductor foundry can manufacture semiconductor devices using the designs of the EDA tool.

If the simulation tool 220 determines that the results of running the simulation file are not acceptable (e.g., Block 435 returns a result of NO), the simulation tool 220 labels the design as unsuccessful. (Block 450). In example operations, users or EDA tools may redesign one or more components of a design responsive to an unsuccessful simulation. In such examples, the simulation tool 220 may simulate the updated design responsive to new design considerations.

Example methods are described with reference to the flowchart illustrated in FIG. 4. However, many other methods of implementing an assembly of the degradation simulation file 230 of FIG. 2 to simulate aging of the transistor model 100 of FIGS. 1 and 2 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 5 is a flowchart representative of example machine-readable instructions or example operations 500 that may be at least one of executed, instantiated, or performed using an example programmable circuitry implementation of the age degradation module 270 of FIGS. 2 and 3 for the transistor model 100 of FIGS. 1 and 2. The example operations 500 begin at block 505 at which the multiplication circuitry 345 sets voltage sources to an initial voltage. In example operations, at an initial time (to), which corresponds to a time immediately following fabrication, hot charge carriers have not had a chance to ionize near the regions 125, 130. At such a time, the ionization region 140 has not formed. In such example operations, the multiplication circuitry 345 sets the voltage sources 105, 115 to zero volts responsive to the damage tracking circuitry 335 having not accumulated any damage resistance (R_{damage}). In other examples, the simulation tool 220 may wait to add the voltage sources 105, 115 to the degradation simulation file 230 until after the initial time.

The age tracking circuitry 310 determines if the time is an initial time. (Block 515). In example operations, the age tracking circuitry 310 waits for the age of the transistor 110 to leave an initial value. In some examples, the age tracking circuitry 310 accumulates a number of cycles of a clock signal to represent the age of the transistor 110. In some such examples, the age flag circuitry 305 prevents the age tracking circuitry 310 from leaving the initial time until the age flag is set. For example, the simulation tool 220 may prevent the simulation of CHC degradation by clearing the age flag of the age flag circuitry 305. Alternatively, if the age flag of the age flag circuitry 305 is set, the age tracking circuitry 310 may leave the initial time after a reference clock cycle. If the age tracking circuitry 310 determines the time is an initial time (e.g., Block 515 returns a result of YES), control proceeds to return to Block 515. In some examples, the initial time may correspond to a range of time less than a threshold age. For example, the age tracking circuitry 310 determines to begin aging the transistor 110 responsive to the age being greater than the threshold age.

If the age tracking circuitry 310 determines the time is not an initial time (e.g., Block 520 returns a result of NO), the age tracking circuitry 310 determines the age of a transistor. (Block 520). In example operations, if the age flag of the age flag circuitry 305 is set, the accumulator circuitry 315 accumulates an age value of the age tracking circuitry 310 to simulate the passage of time.

The channel damage circuitry 325 and the transistor current circuitry 340 determine a drain voltage of the transistor. (Block 525). In some examples, the channel damage circuitry 325 and the transistor current circuitry 340 are coupled to the drain terminal (D) of the transistor model 100. In example operations, the transistor model 100 provides the drain voltage (V_{D}) of the drain terminal to the channel damage circuitry 325 and the transistor current circuitry 340.

The channel damage circuitry 325 and the transistor current circuitry 340 determine a source voltage of the transistor. (Block 530). In some examples, the channel damage circuitry 325 and the transistor current circuitry 340 are coupled to the source terminal(S) of the transistor model 100. In example operations, the transistor model 100 provides the source voltage (V_{S}) of the source terminal to the channel damage circuitry 325 and the transistor current circuitry 340.

The channel damage circuitry 325 and the transistor current circuitry 340 determine a gate voltage of the transistor. (Block 535). In some examples, the channel damage circuitry 325 and the transistor current circuitry 340 are coupled to the gate terminal (G) of the transistor model 100. In example operations, the transistor model 100 provides the gate voltage (V_{G}) of the gate terminal to the channel damage circuitry 325 and the transistor current circuitry 340.

The channel damage circuitry 325 determines a bulk voltage of the transistor. (Block 540). In some examples, the channel damage circuitry 325 is coupled to the bulk terminal (B) of the transistor model 100. In example operations, the transistor model 100 provides the bulk voltage (V_{B}) of the bulk terminal to the channel damage circuitry.

The temperature circuitry 320 determines a temperature of the transistor. (Block 545). In example operation, the temperature circuitry 320 determines a temperature of the transistor model 100 using the temperature estimation module 280. In some examples, the temperature estimation module 280 is another simulation file that estimates the temperature of the transistor 110 during the example operations.

The channel damage circuitry 325 estimates a damage of the transistor using the age, the drain voltage, the source voltage, the gate voltage, the bulk voltage, and the temperature. (Block 550). In example operations, the lateral electrical fields that excessively energize charge carriers are proportional to the voltages of the transistor model 100. For example, a relatively high drain-to-source voltage produces more hot charge carriers in comparison to a relatively low drain-to-source voltage. Similarly, a relatively high gate or drain voltage produces more hot charge carriers in comparison to a relatively low gate or drain voltage. Accordingly, the channel damage circuitry 325 uses voltages of the transistor model 100 to determine the amount of hot charge carriers, which create CHC degradation. In some examples, the channel damage circuitry 325 may further consider the impact of the estimated temperature on the hot charge carriers. For example, the hot charge carriers are less likely to ionize at colder temperatures. Also, in some examples, the channel damage circuitry 325 determines the operating region of the transistor model 100. For example, the channel damage circuitry 325 modifies the output transconductance of the transistor 110 responsive to the transistor model 100 operating in linear or saturation region. Advantageously, adaptively updating the output transconductance reduces the overprediction of CHC degradation in saturation operations. Advantageously, adaptively changing the amount of CHC degradation using voltages of the transistor model 100 increases the accuracy of the simulation of the ionization region 140.

The damage tracking circuitry 335 accumulates the damage of the transistor with previous damage of the transistor. (Block 555). In example operations, the accumulator circuitry 330 accumulates the damage resistance from the channel damage circuitry 325 over time. In such example operations, the accumulator circuitry 330 updates the damage resistance of the damage tracking circuitry 335 to reflect the formation of the ionization region 140 over time.

The transistor current circuitry 340 determines a current of the transistor. (Block 560). In example operations, the transistor current circuitry 340 determines the conduction of current (I_{DS}) by the transistor 110 responsive to the drain, gate, and source voltages (V_{D}, V_{G}, V_{S}) of the transistor model 100. In some examples, the transistor current circuitry 340 uses electrical characteristics of the transistor 110 to determine the current at a given time.

The multiplication circuitry 345 sets voltage sources using the accumulated damage and the current of the transistor. (Block 565). In example operations, the multiplication circuitry 345 multiplies the current (I_{DS}) of the transistor 110 by the damage resistance (R_{damage}) to determine a voltage (V_{DR}) of the voltage sources 105, 115. The multiplication circuitry 345 implements Equation (2). In such example operations, if the determined voltage is greater than zero, the multiplication circuitry 345 sets the voltage sources 105 equal to the determined voltage. In such examples, positive determined voltages represent the formation of the ionization region 140. Alternatively, if the determined voltage is less than zero, the multiplication circuitry 345 sets the voltage source 115 equal to the absolute value of the determined voltage. In such examples, if the determined voltage is a negative voltage, the negative determined voltage corresponds to the ionization of hot charges on the source terminal(S) of the transistor 110. Alternatively, the multiplication circuitry 345 may determine to set the voltage source 115 responsive to the damage resistance being less than a threshold resistance. For example, if the threshold resistance is zero, the multiplication circuitry 345 represents damage resistances less than zero using the voltage source 115.

Advantageously, the transistor model 100 can represent CHC degradation on drain or source terminals of the transistor model 100.

$${V}_{DR} = {I}_{DS} {R}_{damage} \qquad Equation ( 2 )$$

Control proceeds to return to Block 520. Example methods are described with reference to the flowchart illustrated in FIG. 5. However, many other methods of implementing the age degradation module 270 of FIGS. 2 and 3 for the transistor model 100 of FIGS. 1 and 2 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

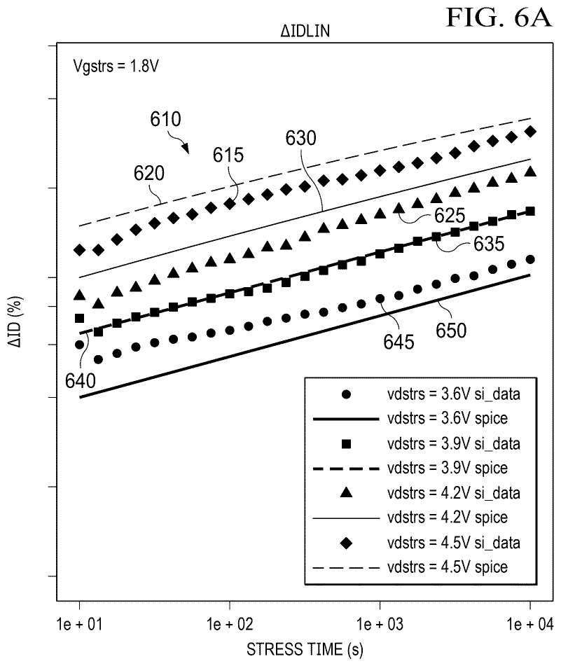

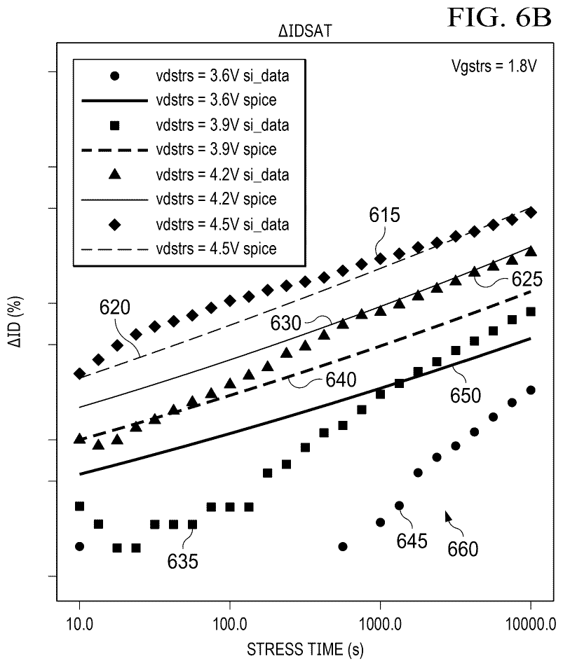

FIG. 6A is a plot 610 of example linear region operations of the transistor 110 of FIGS. 1 and 2 and the age degradation module 270 of FIGS. 2 and 3. The example plot 610 of FIG. 6A includes first measurements 615, a first modeling 620, second measurements 625, second modeling 630, third measurements 635, third modeling 640, fourth measurements 645, and fourth modeling 650. The measurements 615, 625, 635, 645 represent operations of the degradation simulation file 230 to age the transistor 110 across an aging time and a range of drain voltages. The modeling 620, 630, 640, 650 represent the mathematical changes in the current of the transistor 110 across an aging time and a range of drain voltages. In the example of FIG. 6A, the measurements 615, 625, 635, 645 accurately reflect the trends of the modeling 620, 630, 640, 650. Advantageously, the age degradation module 270 accurately models the formation of the ionization region 140 using the voltage sources 105, 115.

FIG. 6B is a plot 660 of example saturation region operations of the transistor 110 of FIGS. 1 and 2 and the age degradation module 270 of FIGS. 2 and 3. The example plot 660 of FIG. 6B includes the measurements 615, 625, 635, 645 of FIG. 6A and the modeling 620, 630, 640, 650 of FIG. 6A for saturation performance. In the example of FIG. 6B, the measurements 615, 625, 635, 645 accurately reflect the trends of the modeling 620, 630, 640, 650 for saturation operations. Advantageously, the age degradation module 270 accurately models the formation of the ionization region 140 using the voltage sources 105, 115 during saturation operations. Advantageously, using the voltage sources 105, 115 and the age degradation module 270 reduce the over estimation of the damage resistance in saturation operating conditions.

In the examples of FIGS. 6A and 6B, the operations of the transistor 110 in linear and saturation regions are asymmetric. For example, in the linear region of operation, illustrated by FIG. 6A, the change in current of the modeling 620, 630, 640, 650 follows the logarithmic changes in the measurements 615, 625, 635, 645. In the example saturation region of operation, illustrated by FIG. 6B. the change in current of the modeling 620, 630, 640, 650 also follows the changes in the measurements 615, 625, 635, 645, which have a different slope in comparison to the slopes of FIG. 6A. For example, in the linear region of FIG. 6A, the modeling 620, 630, 640, 650 have higher slopes in comparison to the slopes of the modeling 620, 630, 640, 650 of saturation operations in FIG. 6B. In such examples, the measurements 615, 625, 635, 645 dynamically change with the slopes of the modeling 620, 630, 640, 650 across linear and saturation operations. Advantageously, the age degradation module 270 accurately models asymmetric changes in the transistor 110.

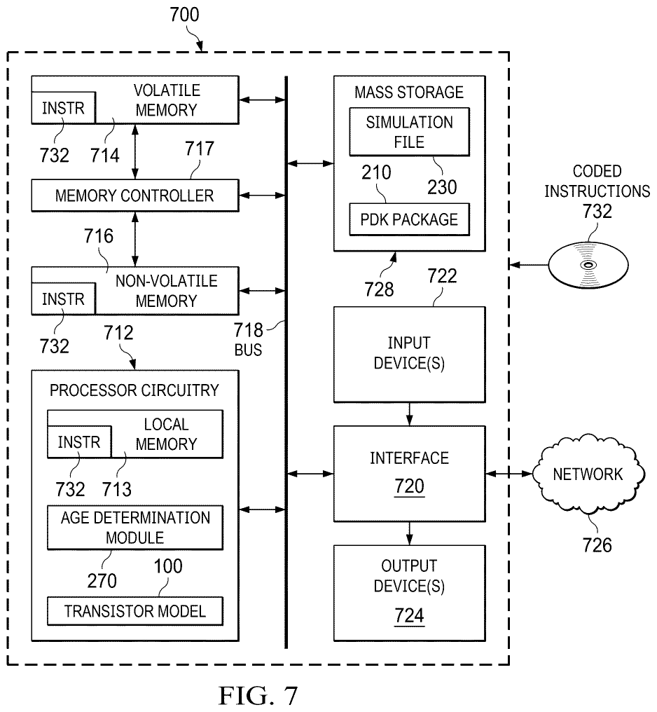

FIG. 7 is a block diagram of an example programmable circuitry platform 700 structured to one or a combination of execute or instantiate one or more of the example machine-readable instructions or the example operations of FIGS. 4 and 5 to implement the age degradation module 270 of FIG. 3. The programmable circuitry platform 700 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing or electronic device.

The programmable circuitry platform 700 of the illustrated example includes programmable circuitry 712. The programmable circuitry 712 of the illustrated example is hardware. For example, the programmable circuitry 712 can be implemented by one or more integrated circuits, logic circuits, FPGAs, microprocessors, CPUs, GPUs, DSPs, or microcontrollers from any desired family or manufacturer. The programmable circuitry 712 may be implemented by one or more semiconductor based (e.g., silicon based) devices. In this example, the programmable circuitry 712 implements the age flag circuitry 305, the age tracking circuitry 310, the accumulator circuitry 315, the temperature circuitry 320, the channel damage circuitry 325, the accumulator circuitry 330, the channel damage tracking circuitry 335, the transistor current circuitry 340, and the multiplication circuitry 345 or more generally the age degradation module 270. The programmable circuitry 712 of the illustrated example includes a local memory 713 (e.g., a cache, registers, etc.). The programmable circuitry 712 of the illustrated example is in communication with main memory 714, 716, which includes a volatile memory 714 and a non-volatile memory 716, by a bus 718. The volatile memory 714 may be implemented by one or more Synchronous Dynamic Random Access Memory (SDRAM), Dynamic Random Access Memory (DRAM), RAMBUS® Dynamic Random Access Memory (RDRAM®), or any other type of RAM device. The non-volatile memory 716 may be implemented by one or a combination of flash memory or any other desired type of memory device. Access to the main memory 714, 716 of the illustrated examples is controlled by a memory controller 717. In some examples, the memory controller 717 may be implemented by one or more integrated circuits, logic circuits, microcontrollers from any desired family or manufacturer, or any other type of circuitry to manage the flow of data going to and from the main memory 714, 716.

The programmable circuitry platform 700 of the illustrated example also includes interface circuitry 720. The interface circuitry 720 may be implemented by hardware in according to any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 722 are connected to the interface circuitry 720. The input device(s) 722 permit(s) a user (e.g., a human user, a machine user, etc.) to enter one of or a combination of data or commands into the programmable circuitry 712. The input device(s) 722 can be implemented by, for example, one of or a combination of an audio sensor, a microphone, a camera (still or video), a keyboard, a button, a mouse, a touchscreen, a trackpad, a trackball, an isopoint device, or a voice recognition system.

One or more output devices 724 are also connected to the interface circuitry 720 of the illustrated example. The output device(s) 724 can be implemented, for example, by one of or a combination of display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, or speaker. The interface circuitry 720 of the illustrated example, thus, includes one of or a combination of a graphics driver card, a graphics driver chip, or graphics processor circuitry such as a GPU.

The interface circuitry 720 of the illustrated example also includes a communication device such as one of or a combination of a transmitter, a receiver, a transceiver, a modem, a residential gateway, a wireless access point, or a network interface to facilitate exchange of data with external machines (e.g., computing devices of any kind) by a network 726. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 700 of the illustrated example also includes one or more mass storage discs or devices 728 to store one or more of firmware, software, or data. Examples of such mass storage discs or devices 728 include one or more magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices and SSDs. For example, the discs or devices may store the example PDK package 210 of FIG. 2 and/or the simulation file 230 of FIG. 2, which contains the simulation data resulting from the execution of the operations 400 of FIG. 4. In other examples, the example PDK package 210 of FIG. 2 and/or the simulation file 230 of FIG. 2 may be stored or made accessible in the main memory 714, 716.

The machine-readable instructions 732, which may be implemented by the machine-readable instructions of FIGS. 4 and 5, may be stored in one of or a combination of the mass storage device 728, in the volatile memory 714, in the non-volatile memory 716, or on at least one non-transitory computer readable storage medium such as a CD or DVD which may be removable.

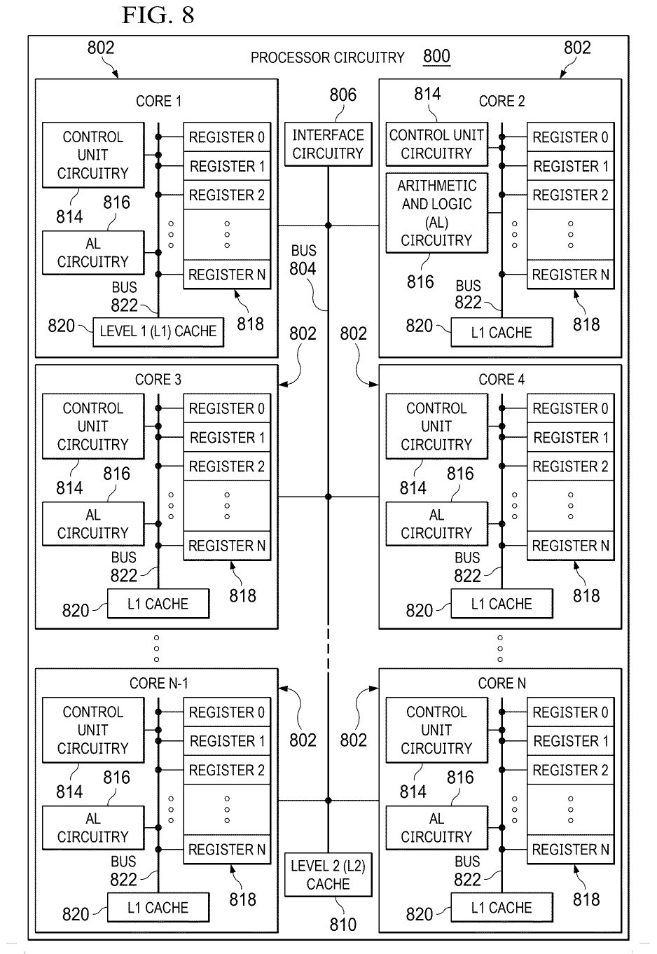

FIG. 8 is a block diagram of an example implementation of the programmable circuitry 712 of FIG. 7. In this example, the programmable circuitry 712 of FIG. 7 is implemented by a microprocessor 800. For example, the microprocessor 800 may be a general-purpose microprocessor (e.g., general-purpose microprocessor circuitry). The microprocessor 800 executes some or all of the machine-readable instructions of the flowcharts of FIGS. 4 and 5 to effectively instantiate the circuitry of FIG. 2 as logic circuits to perform operations corresponding to those machine-readable instructions. In some such examples, the circuitry of FIG. 3 is instantiated by the hardware circuits of the microprocessor 800 in combination with the machine-readable instructions. For example, the microprocessor 800 may be implemented by multi-core hardware circuitry such as a CPU, a DSP, a GPU, an XPU, etc. Although it may include any number of example cores 802 (e.g., 1 core), the microprocessor 800 of this example is a multi-core semiconductor device including N cores. The cores 802 of the microprocessor 800 may operate independently or may cooperate to execute machine-readable instructions. For example, machine code corresponding to a firmware program, an embedded software program, or a software program may be executed by one of the cores 802 or may be executed by multiple ones of the cores 802 at the same or different times. In some examples, the machine code corresponding to the firmware program, the embedded software program, or the software program is split into threads and executed in parallel by two or more of the cores 802. The software program may correspond to a portion or all of the machine-readable instructions or operations represented by the flowcharts of FIGS. 4 and 5.

The cores 802 may communicate by a first example bus 804. In some examples, the first bus 804 may be implemented by a communication bus to effectuate communication associated with one(s) of the cores 802. For example, the first bus 804 may be implemented by at least one of an Inter-Integrated Circuit (I2C) bus, a Serial Peripheral Interface (SPI) bus, a PCI bus, or a PCIe bus. Also or alternatively, the first bus 804 may be implemented by any other type of computing or electrical bus. The cores 802 may receive data, instructions, and signals from one or more external devices by example interface circuitry 806. The cores 802 may output data, instructions, and signals to the one or more external devices by the interface circuitry 806. Although the cores 802 of this example include example local memory 820 (e.g., Level 1 (L1) cache that may be split into an L1 data cache and an L1 instruction cache), the microprocessor 800 also includes example shared memory 810 that may be shared by the cores (e.g., Level 2 (L2 cache)) for high-speed access to data and instructions. Data and instructions may be transferred (e.g., shared) by one of or a combination of writing to or reading from the shared memory 810. The local memory 820 of each of the cores 802 and the shared memory 810 may be part of a hierarchy of storage devices including multiple levels of cache memory and the main memory (e.g., the main memory 714, 716 of FIG. 7). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 802 may be referred to as a CPU, DSP, GPU, etc., or any other type of hardware circuitry. Each core 802 includes control unit circuitry 814, arithmetic and logic (AL) circuitry (sometimes referred to as an ALU) 816, a plurality of registers 818, the local memory 820, and a second example bus 822. Other structures may be present. For example, each core 802 may include vector unit circuitry, single instruction multiple data (SIMD) unit circuitry, load/store unit (LSU) circuitry, branch/jump unit circuitry, floating-point unit (FPU) circuitry, etc. The control unit circuitry 814 includes semiconductor-based circuits structured to control (e.g., coordinate) data movement within the corresponding core 802. The AL circuitry 816 includes semiconductor-based circuits structured to perform one or more mathematic or logic operations on the data within the corresponding core 802. The AL circuitry 816 of some examples performs integer-based operations. In other examples, the AL circuitry 816 also performs floating-point operations. In yet other examples, the AL circuitry 816 may include first AL circuitry that performs integer-based operations and second AL circuitry that performs floating-point operations. In some examples, the AL circuitry 816 may be referred to as an Arithmetic Logic Unit (ALU).

The registers 818 are semiconductor-based structures to store data and instructions such as results of one or more of the operations performed by the AL circuitry 816 of the corresponding core 802. For example, the registers 818 may include vector register(s), SIMD register(s), general-purpose register(s), flag register(s), segment register(s), machine-specific register(s), instruction pointer register(s), control register(s), debug register(s), memory management register(s), machine check register(s), etc. The registers 818 may be arranged in a bank as shown in FIG. 8. Alternatively, the registers 818 may be organized in any other arrangement, format, or structure, such as by being distributed throughout the core 802 to shorten access time. The second bus 822 may be implemented by at least one of an I2C bus, a SPI bus, a PCI bus, or a PCIe bus.

Each core 802 or, more generally, the microprocessor 800 may include additional or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) or other circuitry may be present. The microprocessor 800 is a semiconductor device fabricated to include many transistors interconnected to implement the structures described above in one or more integrated circuits (ICs) contained in one or more packages.

The microprocessor 800 may include or cooperate with one or more accelerators (e.g., acceleration circuitry, hardware accelerators, etc.). In some examples, accelerators are implemented by logic circuitry to perform certain tasks more quickly and efficiently than can be done by a general-purpose processor. Examples of accelerators include ASICs and FPGAs such as those described herein. A GPU, DSP, or other programmable device can also be an accelerator. Accelerators may be on-board the microprocessor 800, in the same chip package as the microprocessor 800, or in one or more separate packages from the microprocessor 800.

Although FIG. 8 illustrates an example implementation of the programmable circuitry 712 of FIG. 7, many other approaches are contemplated. For example, FPGA circuitry may include an on-board CPU, such as one or more of the example CPUs. Therefore, the programmable circuitry 712 of FIG. 7 may also be implemented by combining at least the example microprocessor 800 of FIG. 8 and example FPGA circuitry. In some such hybrid examples, one or more cores 802 of FIG. 8 may execute a first portion of the machine-readable instructions represented by the flowchart(s) of FIGS. 4 and 5 to perform first operation(s)/function(s), and/or an ASIC may be at least one of configured or structured to perform second operation(s)/function(s) corresponding to a second portion of the machine-readable instructions represented by the flowcharts of FIGS. 4 and 5.

Some or all of the circuitry of FIG. 3 may, thus, be instantiated at the same or different times. For example, same and/or different portion(s) of the microprocessor 800 of FIG. 8 may be programmed to execute portion(s) of machine-readable instructions at the same and/or different times.

In some examples, some or all of the circuitry of FIG. 3 may be instantiated, for example, in one or more threads executing concurrently and/or in series. For example, the microprocessor 800 of FIG. 8 may execute machine-readable instructions in one or more threads executing concurrently and/or in series. Moreover, in some examples, some or all of the circuitry of FIG. 3 may be implemented within one or more virtual machines or containers executing on the microprocessor 800 of FIG. 8.

In some examples, the programmable circuitry 712 of FIG. 7 may be in one or more packages. For example, the microprocessor 800 of FIG. 8 may be in one or more packages. In some examples, an XPU may be implemented by the programmable circuitry 712 of FIG. 7, which may be in one or more packages. For example, the XPU may include a CPU (e.g., the microprocessor 800 of FIG. 8, etc.) in one package, a DSP in another package, a GPU in yet another package, and an FPGA in still yet another package.

While an example manner of implementing the transistor model 100 and the age degradation module 270 of FIG. 1 is illustrated in FIG. 3, one or more of the elements, processes, or devices illustrated in FIG. 3 may be combined, divided, re-arranged, omitted, eliminated, or implemented in any other way. Further, implements the age flag circuitry 305, the age tracking circuitry 310, the accumulator circuitry 315, the temperature circuitry 320, the channel damage circuitry 325, the accumulator circuitry 330, the channel damage tracking circuitry 335, the transistor current circuitry 340, and the multiplication circuitry 345 or more generally the age degradation module 270 of FIG. 3, may be implemented by hardware alone or by hardware in combination with software and firmware. Thus, for example, any of the implements the age flag circuitry 305, the age tracking circuitry 310, the accumulator circuitry 315, the temperature circuitry 320, the channel damage circuitry 325, the accumulator circuitry 330, the channel damage tracking circuitry 335, the transistor current circuitry 340, and the multiplication circuitry 345 or more generally the age degradation module 270, could be implemented by programmable circuitry in combination with one or more machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the transistor model 100 and the example age degradation module 270 of FIG. 3 may include one or more elements, processes, or devices in addition to, or instead of, those illustrated in FIGS. 2 and/or 3, or may include more than one of any or all of the illustrated elements, processes and devices.

Flowchart(s) representative of example machine-readable instructions, which may be executed by programmable circuitry to at least one of implement or instantiate the transistor model 100 and the age degradation module 270 of FIG. 3 or representative of example operations which may be performed by programmable circuitry to at least one of implement or instantiate the transistor model 100 and the age degradation module 270 of FIG. 3, are shown in FIGS. 4 and 5. The machine-readable instructions may be one or more executable programs or portion(s) of one or more executable programs for execution by programmable circuitry such as the programmable circuitry 712 shown in the example processor platform 700 described below in connection with FIG. 7 and may be one or more function(s) or portion(s) of functions to be performed by the example programmable circuitry (e.g., an FPGA) described below in connection with FIG. 8. In some examples, the machine-readable instructions cause an operation, a task, etc., to be carried out or performed in an automated manner in the real-world. As used herein, “automated” means without human involvement.

The program may be embodied in instructions (e.g., software and/or firmware) stored on one or more non-transitory computer readable and/or machine-readable storage medium such as one of or a combination of cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), or any other storage device or storage disk. The instructions of the non-transitory computer readable and/or machine-readable medium may program or be executed by programmable circuitry located in one or more hardware devices, but the entire program or parts thereof could alternatively be executed or instantiated by one or more hardware devices other than the programmable circuitry or embodied in dedicated hardware. The machine-readable instructions may be distributed across multiple hardware devices or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 4 and 5, many other methods of implementing the example transistor model 100 and the age degradation module 270 may alternatively be used. For example, the order of execution of the blocks of the flowchart(s) may be changed, or some of the blocks described may be changed, eliminated, or combined. Also or alternatively, any or all of the blocks of the flow chart may be implemented by one or more hardware circuits (e.g., processor circuitry, discrete, integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations or local to one or more hardware devices (e.g., a single-core processor (e.g., a single core CPU), a multi-core processor (e.g., a multi-core CPU, an XPU, etc.)). As used herein, programmable circuitry includes any type(s) of circuitry that may be programmed to perform a desired function such as, for example, one of or a combination of a CPU or an FPGA. The programmable circuitry may include one or more CPUs and/or one or more FPGAs located in the same package (e.g., the same integrated circuit (IC) package or in two or more separate housings), one or more CPUs or FPGAs in a single machine, one or multiple CPUs or FPGAs distributed across multiple servers of a server rack, multiple processors distributed across one or more server racks. Also or alternatively, programmable circuitry may include a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc., or any combination(s) thereof in any of the contexts described above.

The machine-readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, or produce machine executable instructions. For example, the machine-readable instructions may be fragmented and stored on one or more storage devices, disks or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, or executable by a computing device or other machine. For example, the machine-readable instructions may be stored in multiple parts, which are individually compressed, encrypted, or stored on separate computing devices, wherein the parts when decrypted, decompressed, or combined form a set of one or more computer-executable or machine executable instructions that implement one or more functions or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions or the corresponding program(s) can be executed in whole or in part. Thus, machine-readable, computer readable or machine-readable media, as used herein, may include one or a combination of instructions and program(s) regardless of the particular format or state of the machine-readable instructions or program(s).

The machine-readable instructions described herein can be represented by any past, present, or future instruction language, scripting language, programming language, etc. For example, the machine-readable instructions may be represented using any of the following languages: C, C++, Java, C-Sharp, Perl, Python, JavaScript, HyperText Markup Language (HTML), Structured Query Language (SQL), Swift, etc.

As mentioned above, the example operations of FIGS. 4 and 5 may be implemented using executable instructions (e.g., computer readable and/or machine-readable instructions) stored on one or more non-transitory computer readable or machine-readable media. As used herein, the terms non-transitory computer readable medium, non-transitory computer readable storage medium, non-transitory machine-readable medium, and non-transitory machine-readable storage medium are expressly defined to include any type of computer readable storage device or storage disk and to exclude propagating signals and to exclude transmission media. Examples of such non-transitory computer readable medium, non-transitory computer readable storage medium, non-transitory machine-readable medium, or non-transitory machine-readable storage medium include one or more optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, for caching of the information). As used herein, the terms “non-transitory computer readable storage device” and “non-transitory machine-readable storage device” are defined to include any physical (mechanical, magnetic, electromechanical, or electrical) hardware to retain information for a time period, but to exclude propagating signals and to exclude transmission media. Examples of non-transitory computer readable storage devices or non-transitory machine-readable storage devices include one or a combination of random-access memory of any type, read only memory of any type, solid state memory, flash memory, optical discs, magnetic disks, disk drives, or redundant array of independent disks (RAID) systems. As used herein, the term “device” refers to physical structure such as one of or a combination of mechanical, electromechanical, or electrical equipment, hardware, or circuitry that may or may not be configured by computer readable instructions, machine-readable instructions, etc., or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

What is claimed is:

1. A method comprising:
generating a simulation file to simulate a circuit, wherein the circuit includes a transistor including a drain terminal, a source terminal, and a gate terminal, and wherein the simulation file models the transistor with a voltage source coupled to the source terminal;
setting a magnitude of the voltage source in the simulation file using an age of the transistor, an estimated voltage at the drain terminal, and an estimated voltage at the gate terminal; and
running the simulation file using the magnitude of the voltage source to simulate the circuit.

2. The method of claim 1,
wherein the voltage source is a first voltage source,
wherein the circuit includes a second voltage source coupled to the drain terminal of the transistor,
wherein the method further comprises setting a magnitude of the second voltage source in the simulation file using the age of the transistor, the estimated voltage at the drain terminal, and the estimated voltage at the source terminal, and
wherein running the simulation file comprises running the simulation file using the magnitude of the first voltage source and using the magnitude of the second voltage source to simulate the circuit.

3. The method of claim 1, further comprising estimating a damage resistance of the transistor using the using the age of the transistor, the estimated voltage at the drain terminal, and the estimated voltage at the gate terminal,
wherein setting the magnitude of the voltage source uses the damage resistance.

4. The method of claim 1, further comprising generating a design for a semiconductor device using the simulation file.

5. The method of claim 1, further comprising fabricating a semiconductor device using the simulation file.

6. The method of claim 5, wherein the semiconductor device includes a physical implementation of the circuit and the transistor.

7. The method of claim 1, wherein setting the magnitude of the voltage source uses the age of the transistor, the estimated voltage at the drain terminal, the estimated voltage at the gate terminal, and an estimated temperature of the circuit.

8. The method of claim 1, wherein setting the magnitude of the voltage source uses the age of the transistor, the estimated voltage at the drain terminal, the estimated voltage at the gate terminal, and an estimated voltage at the source terminal.

9. The method of claim 1,
wherein the transistor includes a bulk terminal, and
wherein setting the magnitude of the voltage source uses the age of the transistor, the estimated voltage at the drain terminal, the estimated voltage at the gate terminal, and an estimated voltage at the bulk terminal.

10. The method of claim 1, wherein setting the magnitude of the voltage source uses the age of the transistor, the estimated voltage at the drain terminal, the estimated voltage at the gate terminal, and a current of the transistor.

11. The method of claim 1, further comprising setting the magnitude of the voltage source to an initial voltage responsive to a determination that the age of the transistor is less than a threshold age.

12. The method of claim 1, further comprising setting the magnitude of the voltage source to a negative voltage responsive to a determination that a damage resistance of the transistor is less than a threshold resistance.

13. At least one non-transitory computer readable storage medium comprising instructions that, when executed, cause programmable circuitry to at least:
generate a simulation file to simulate a circuit, wherein the circuit includes a transistor including a drain terminal, a source terminal, and a gate terminal, and wherein the simulation file models the transistor with a voltage source coupled to the source terminal;
set a magnitude of the voltage source in the simulation file using an age of the transistor, an estimated voltage at the drain terminal, and an estimated voltage at the gate terminal; and
run the simulation file using the magnitude of the voltage source to simulate the circuit.

14. The at least one non-transitory computer readable storage medium of claim 13,
wherein the voltage source is a first voltage source,
wherein the circuit includes a second voltage source coupled to the drain terminal of the transistor,
wherein the instructions, when executed, cause the programmable circuitry to set a magnitude of the second voltage source in the simulation file using the age of the transistor, the estimated voltage at the drain terminal, and the estimated voltage at the source terminal, and
wherein the instructions to run the simulation file comprise instructions to run the simulation file using the magnitude of the first voltage source and using the magnitude of the second voltage source to simulate the circuit.

15. The at least one non-transitory computer readable storage medium of claim 13,
wherein setting the magnitude of the voltage source uses the age of the transistor, the estimated voltage at the drain terminal, the estimated voltage at the gate terminal, and an estimated temperature of the circuit.

16. The at least one non-transitory computer readable storage medium of claim 13,
wherein the transistor includes a bulk terminal, and
wherein setting the magnitude of the voltage source uses the age of the transistor, the estimated voltage at the drain terminal, the estimated voltage at the gate terminal, an estimated voltage at the source terminal, and an estimated voltage at the bulk terminal.

17. A method comprising:
generating a simulation file to simulate a circuit, wherein the circuit includes a transistor including a drain terminal and a gate terminal, and wherein the simulation file models the transistor with a voltage source coupled to the drain terminal;
setting a magnitude of the voltage source in the simulation file using an age of the transistor, an estimated voltage at the drain terminal, and an estimated voltage at the gate terminal; and
running the simulation file using the magnitude of the voltage source to simulate the circuit.

18. The method of claim 17,
wherein the transistor includes a source terminal,
wherein the voltage source is a first voltage source,
wherein the circuit includes a second voltage source coupled to the source terminal of the transistor,
wherein the method further comprises setting a magnitude of the second voltage source in the simulation file using the age of the transistor, the estimated voltage at the drain terminal, and the estimated voltage at the source terminal, and
wherein running the simulation file comprises running the simulation file using the magnitude of the first voltage source and using the magnitude of the second voltage source to simulate the circuit.

19. The method of claim 17, wherein setting the magnitude of the voltage source uses the age of the transistor, the estimated voltage at the drain terminal, the estimated voltage at the gate terminal, and an estimated temperature of the circuit.

20. The method of claim 17,
wherein the transistor includes a source terminal and a bulk terminal, and
wherein setting the magnitude of the voltage source uses the age of the transistor, the estimated voltage at the drain terminal, the estimated voltage at the gate terminal, an estimated voltage at the source terminal, and an estimated voltage at the bulk terminal.
